(19) United States
(12) Patent Application Publication
(10) Pub. No.: US 2010/0215891 A1
(43) Pub. Date: Aug. 26, 2010

(54) RECORDING MEDIUM AND MANUFACTURING METHOD OF RECORDING MEDIUM

(76) Inventors: Jin Hong Kim, Seoul (KR); Jun Seok Lee, Seoul (KR); Jung Shik Lim, Seoul (KR); Hun Seo, Seoul (KR)

Correspondence Address: BIRCH STEWART KOLASCH & BIRCH, PO BOX 747, FALLS CHURCH, VA, 22040-0747, US

(21) Appl. No.: 12/738,465

(22) PCT Filed: Oct. 16, 2008
(86) PCT No.: PCT/KR2008/006119

§ 371 Date: Apr. 16, 2010

(30) Foreign Application Priority Data
Oct. 17, 2007 (KR) 10-2007-0104412
Nov. 12, 2007 (KR) 10-2007-0114951

(51) Int. Cl. B32B 7/02; C23C 16/00

(52) U.S. Cl. 428/64.4; 427/255.6; 427/248.1; 427/255.7; 427/162

(57) ABSTRACT

A recording medium and a method for manufacturing the same are disclosed. More particularly, a recording medium having a high density and high energy transfer efficiency and a method for manufacturing the same are disclosed. The recording medium includes a substrate, a recording layer formed on the substrate, a first cover layer having a first hardness formed on the recording layer, and a second cover layer having a second hardness arranged on the first cover layer.

### TECHNICAL FIELD

The present invention relates to a recording medium and a method for manufacturing the same, and more particularly, to a recording medium having a high density and high energy transfer efficiency and a method for manufacturing the same.

### BACKGROUND ART

The recent rapid development of technology has brought about high-capacity recording media. Examples of such recording media include compact discs (CDs), digital versatile discs (DVDs), etc. In addition to these recording media, there are blu-ray discs and near field recording media with dramatically higher capacity as next-generation recording media. Energy transfer efficiency, enabling recording of recording media is important for such a recording medium. Collision often occurs between a recording medium and a recording/reproducing apparatus due to relatively small distance therebetween. Accordingly, there is a need for a recording medium that has high energy transfer efficiency and superior physical properties enough to protect the same from mechanical collision.

### DISCLOSURE

### Technical Problem

An object of the present invention devised to solve the problem lies on a recording medium having a high density and high energy transfer efficiency and a method for manufacturing the same.

### Technical Solution

The object of the present invention can be achieved by providing a recording medium comprising: a substrate; a recording layer formed on the substrate; a first cover layer having a first hardness formed on the recording layer; and a second cover layer having a second hardness formed on the first cover layer.

In another aspect of the present invention, provided herein is a method for manufacturing a recording medium, comprising: forming a recording layer on a substrate; forming a first cover layer having a first hardness on the recording layer; and forming a second cover layer having a second hardness on the first cover layer.

The second hardness may be higher than the first hardness.

The first hardness may be 2H or less.

The second hardness may be 2H or higher.

The first cover layer may have a first refractive index and the second cover layer may have a second refractive index.

The second refractive index may be higher than the first refractive index.

The recording medium may be recorded/reproduced by a recording/reproducing apparatus comprising an optical system.

The second refractive index of the second cover layer of the recording medium may be higher than a numerical aperture of the optical system.

The first cover layer may be composed of at least one of a polymer and a nanocomposite.

The second cover layer may be composed of at least one dielectric material.

The second cover layer may comprise at least one of Si₃N₄ and ZnS.

The second cover layer may comprise silicon oxide (SiO₂).

The second cover layer may further comprise metal oxide.

The second cover layer may be composed of a compound, (SiO₂)₁₋ₓ+(metal oxide)ₓ.

In the compound, x is 0.1 to 0.9.

In the compound, x is 0.2 to 0.8.

The metal oxide may be at least one selected from Ti, V, Cr, Mn, Fe, Co, Ni, Cu, Zn, Zr, Nb, Mo, Tc, Ru, Rh, Pd, Ag, Hf, Ta, W, Re, W, Os, Ir, Pt, Al, Ge, In and Sn oxides.

The second cover layer may have a refractive index of 1.5 to 2.2.

A total thickness of the first cover layer and the second cover layer may be 1 to 5 μm.

The second cover layer may be an anti-reflective layer.

### DESCRIPTION OF DRAWINGS

The accompanying drawings, which are included to provide a further understanding of the invention, illustrate embodiments of the invention and together with the description serve to explain the principle of the invention.

In the drawings:

FIG. 1 illustrates phase-transition of a material used for a recording layer of the present invention.

FIG. 2 illustrates phase-transition conditions of a recording layer of a recording medium according to the present invention.

FIG. 3 illustrates correlation between a beam incident to a recording medium according to the present invention and a beam refracted therefrom.

FIG. 4 illustrates reflection state of a beam depending on a refractive index of the recording medium according to the present invention.

FIG. 5 illustrates reflection state of a beam depending on a refractive index of the recording medium according to the present invention.

FIG. 6 illustrates reflection state of a beam depending on a refractive index of the recording medium according to the present invention.

FIG. 7 illustrates reflection state of a beam depending on a refractive index of the recording medium according to the present invention.

FIG. 8 illustrates a recording medium according to one embodiment of the present invention.

FIG. 9 illustrates a cover layer according to one embodiment of the present invention.

FIG. 10 illustrates a recording medium according to another embodiment of the present invention.

### BEST MODE

Reference will now be made in detail to the preferred embodiments of the present invention, examples of which are illustrated in the accompanying drawings.

Although most terms used in the present invention have been selected from general ones widely used in the art, some terms have been arbitrarily selected by the applicant and their meanings are explained in detail in the following description as needed. Thus, the present invention should be understood with the intended meanings of the terms rather than their simple names or meanings.

The term “recording medium” as used herein refers to all media storing data recorded or recording data. For example, regardless of a recording manner such as discs and magnetic tapes, the recording medium includes all media.

Hereinafter, for a better understanding, the present invention will be illustrated with reference to one example of a disc, in particular, a near field recording medium. It is obvious that the technical concept of the present invention is applicable to other recording media.

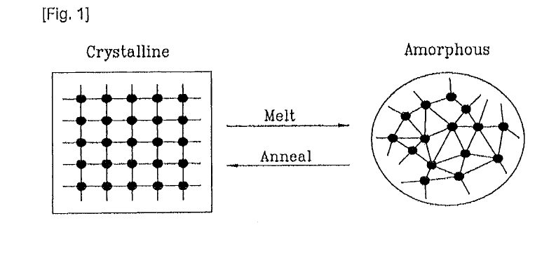

FIG. 1 is a view illustrating a constituent material of a recording layer of a recording medium according to one embodiment of the present invention. FIG. 1 shows status of a phase-transition material constituting the recording layer. The phase-transition material determines its phase, depending on atomic arrangement thereof. As shown in the left of FIG. 1, atoms are arranged at respective lattice sites. This state is referred to as “crystalline” and is a minimum energy state. When crystalline atoms are melted and then rapidly cooled, they deviate from their original positions and are then scattered (shown in the right of FIG. 1). This state is referred to as “amorphous” and is a high energy state, as compared to the crystalline state.

In the case where a recording material constituting the recording layer is crystalline or amorphous, the crystalline and amorphous recording materials differ from each other in refractive index. Accordingly, based on the difference in optical properties, i.e., the refractive index, digital recording and reproduction represented by either “0” or “1” can be realized. In addition, crystalline and amorphous materials have different reflectivity. Crystalline materials exhibit superior optical properties, as compared to amorphous materials. For example, such a phase-transition material may be GeSbTe.

FIG. 2 illustrates a phenomenon in which a recording layer of a recording medium according to the present invention undergoes crystallization and amorphization. FIG. 2 also shows an example of the conditions, enabling crystallization and amorphization of the recording layer of the recording medium.

The left curve in FIG. 2 shows crystallization conditions of a phase-transition material constituting the recording layer of the recording medium. The left curve of FIG. 2 shows the case where a phase-transition material is slowly cooled, after annealing at a crystallization temperature (T_{cry}) or higher. In this curve, Δt′ represents a period of time for which the phase-transition material maintains a crystallization temperature (T_{cry}) or higher.

The right curve in FIG. 2 shows amorphization conditions of a phase-transition material constituting the recording layer. The right curve of FIG. 2 shows the case where a phase-transition material is rapidly cooled, after annealing at a melting temperature (Tₘₑₗₜ) or higher. The amorphous material has a high energy, as compared to the crystalline material.

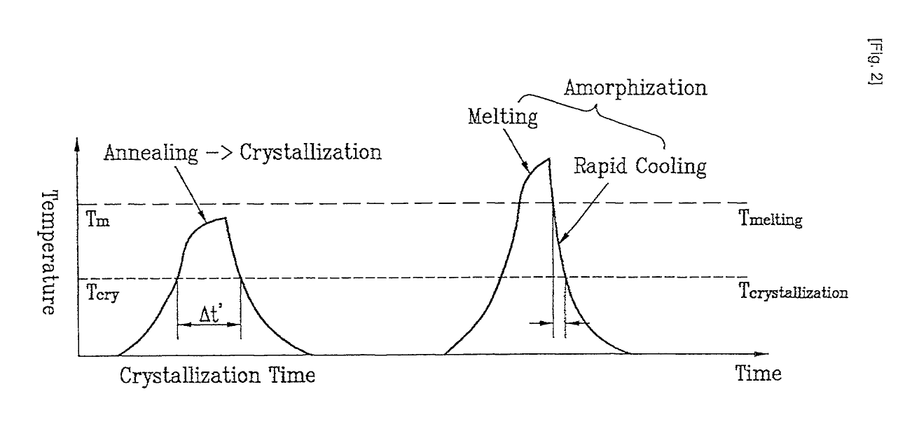

FIG. 3 illustrates a recording method of a recording medium according to one embodiment of the present invention. As mentioned above, for a better description of the recording medium, a near field recording medium will be illustrated as one example. However, it is obvious that this description is also applicable to other recording media.

The recording medium of the present invention uses a phase-transition material to constitute a recording layer and thus perform a recording operation, thereby improving a recording density. However, a near-field recording technique may be used to further improve recording density. A semi-spherical object shown in FIG. 3 is a solid immersion lens (SIL). The SIL serves to increase a numerical aperture and thus improve a recording density of the recording medium.

The recording density of the recording medium is related to the intensity of laser light focused thereupon. In addition, other parameters having an effect on the intensity of the focused laser are light wavelength (λ) of a light source and numerical aperture (NA) of a lens. The recording density may be represented by the following equation:

$$D = 1.22 \frac{λ}{NA}$$

As can be seen from the equation, the shorter the wavelength of the light source (or the higher the numerical aperture), the greater the density of the laser light. The wavelength of the light source may be in the range from 400 nm to 700 nm. As one method for increasing the numerical aperture, a material having a high refractive index may be used for light focusing. Examples of this material include solid immersion lenses (SILs) and solid immersion mirrors (SIMs). For example, when such a material is not used, a maximum numerical aperture is only 0.85, whereas, when SIL or SIM is used, the numerical aperture can be increased up to 1.5 to 2. In addition, near field recording refers to a recording method with an increased numerical aperture using SIL or SIM to increase a numerical aperture. By using the phase-transition material in conjunction with short wavelength and near field recording, the recording density of recording media can be increased.

In addition, for near field recording, energy transfer efficiency between the recording medium and the recording/reproducing apparatus is important. For this purpose, near field recording may be designed, taking into consideration optical properties of the recording medium and the recording apparatus. For example, the recording medium may be manufactured, taking into consideration refractive indices of the recording medium and the recording apparatus.

As shown in FIG. 3, a beam is incident at an angle (θᵢ) in an SIL whose refractive index is nᵢ. The following equation can be derived from Snell's law, in terms of a refractive angle of a transmitting beam (θₜ) and a refractive angle of a transmitted medium (nₜ), e.g., an uppermost layer of the recording medium,

nᵢ sin θᵢ=nₜ sin θₜ

wherein when θₜ=90°, NA=nₜ and NA=nᵢ sin θᵢ (in which NA means numerical aperture of an optical system which belongs to an apparatus for recording and/or reproducing a recording medium), and in addition, when θₜ=90°, light entering a recording medium is not incident on the recording medium and undergoes total reflection. Accordingly, in order to transfer a beam to the recording medium without causing total reflection, the condition of θₜ≦90°, i.e., NA≦nₜ is required.

That is, in order to transfer a beam passing through a near field generator to the recording medium without total reflection, the condition, nₜ≧NA, must be satisfied. In this case, NA may be determined, depending on optical properties of an optical system for recording/reproducing a recording medium.

FIG. 4 illustrates one example where a refractive index of the uppermost layer of the recording medium is less than the NA value of the recording apparatus. As mentioned above, when nₜ≦NA, a beam hardly transfers from the recording apparatus to the recording medium, and the beam entering the recording medium from the recording/reproducing apparatus undergoes total reflection.

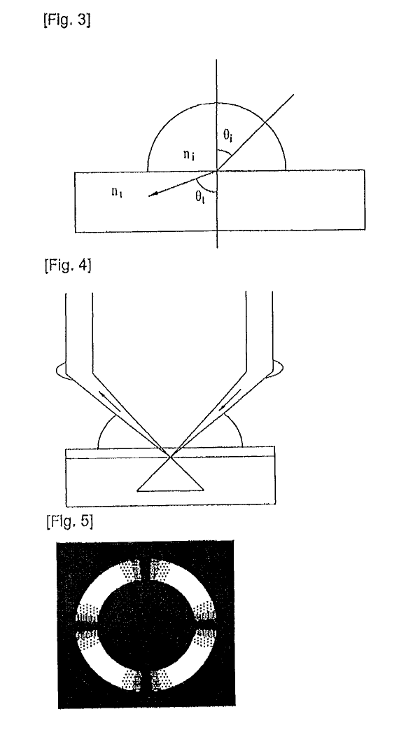

FIG. 5 illustrates the case where a beam incident to the recording medium is totally reflected from the recording medium.

That is, in FIG. 5, if nₜ≦NA, a beam is incident to the recording medium. It can be seen from a reflected donut-shape beam that a beam incident to the recording medium is totally reflected. In this case, efficiency of beam transfer to the recording medium is low, making efficient recording and reproduction difficult.

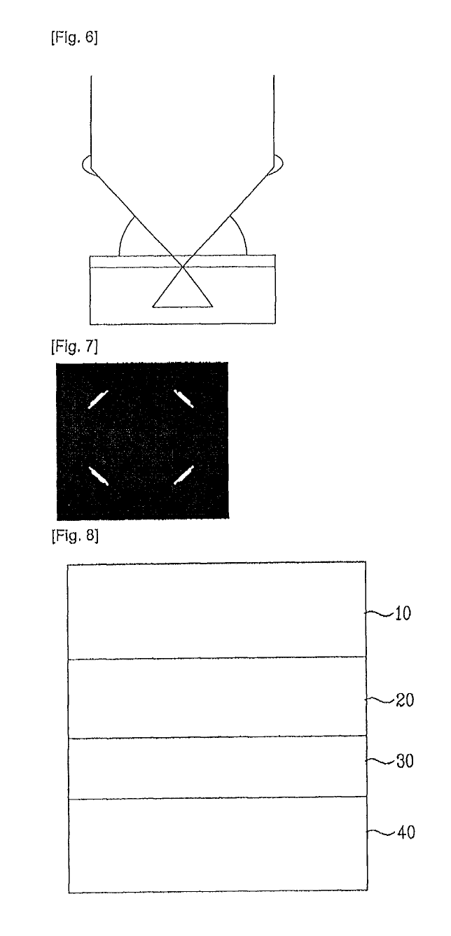

FIG. 6 illustrates one embodiment where refractive index (nₜ) of the uppermost layer of the recording medium is higher than the NA value of the recording apparatus. In this case, without reflection between the recording medium and the recording apparatus, a beam is emitted from the recording apparatus to the recording medium.

FIG. 7 illustrates one example of beam reflection derived from the recording medium. Reflection of a beam from the recording medium is minimal. That is, energy transfer efficiency from the recording apparatus to the recording medium is high. To increase the energy transfer efficiency of the uppermost layer of the recording medium, the refractive index of the uppermost layer may be higher than NA of the recording/reproducing apparatus, (e.g., an optical system). For example, a recording/reproducing apparatus employing a near field optical system may have an NA of 1.5 or higher. In this case, the uppermost layer (or a cover layer) of the recording medium may have a refractive index of 1.5, so as to secure high energy transfer efficiency.

In addition to optical properties such as refractive index, the uppermost layer of the recording medium may require suitable mechanical properties. That is, to minimize damage due to scratches or physical collision, suitable hardness may be required. For this purpose, the recording medium requires a cover layer, and more specifically, may include one cover layer or a plurality of cover layers having different optical and mechanical properties to satisfy the afore-mentioned optical and mechanical properties.

FIG. 8 is a sectional view illustrating a recording medium according to one embodiment of the present invention. In this embodiment, the recording medium comprises a second cover layer 10, a first cover layer 20, an information layer 30 and a substrate 40.

In addition, the second cover layer 10 requires a suitable hardness. The suitable hardness serves to protect the recording medium. In particular, in the case of the near field recording medium, provided as one example, because the distance between a near field generator and a recording medium is less than 100 nm, collision therebetween may frequently occur. In addition to lenses, the recording medium may be scratched. The cover layer of the recording medium may maintain a suitable hardness to prevent scratches. For example, the hardness required to prevent scratches of conventional lenses may be 2H (based on a pencil hardness tester). Obviously, the hardness of the second cover layer may be expressed, based on other hardness testers. In addition, the refractive index of the second cover layer may be set such that it is higher than the NA of the recording apparatus, as mentioned above.

In addition, the second cover layer may comprise a first cover layer formed in a lower part. A material for the first cover layer may be at least one of a polymer and a nanocomposite.

In addition, when the second cover layer is made of a material whose thickness is difficult to control, the first cover layer is made of a material whose thickness is easily controlled. For example, the second cover layer may be formed using a sputtering method, wherein thickness is, disadvantageously, hard to control.

In addition, when the second cover layer secures a sufficient hardness, the hardness of the first cover layer may be lower than that of the second cover layer. In addition, the hardness of the first cover layer and the hardness of the second cover layer refer to a first hardness and a second hardness, respectively. For example, the second cover layer has a hardness of 2H or higher, the first cover layer may have a hardness of 2H or less. In addition, for efficient beam transfer, a refractive index of the first cover layer may be lower than that of the second cover layer.

The thickness of the first and second cover layers may be expressed as a total thickness of the two cover layers. For example, the total thickness of the first cover layer and the second cover layer may be 1 to 5 μm. Alternatively, only the thickness of the second cover layer may be used without the first cover layer.

The second cover layer may serve as an anti-reflective layer. For this purpose, it is necessary to adjust the thickness and refractive index to a desired level. In this regard, the recording medium is related to factors such as the thickness and refractive index of a substrate, or refractive index of a protective film arranged on the substrate. The term “anti-reflective layer” as used herein refers to a layer serving to offset a beam incident to the recording medium and thus to prevent reflection of the beam. That is, the beam incident to the recording medium passes through the recording layer and may then be reflected from the substrate or protective film thereof. In this case, a beam reflected through the substrate or the protective film of the substrate may affect recording and reproducing operations of the recording medium. Thus, by suitably controlling the thickness of the second cover layer 10, a beam reflected from the second cover layer and the substrate and/or protective film thereof can be offset.

The second cover layer 10 may comprise at least one dielectric material. The dielectric material may be Si₃N₄ or ZnSr, which has a relatively large refractive index. Other useful dielectric materials include combinations of Si₃N₄ or ZnS, and SiO₂, i.e., Si₃N₄—SiO₂ or ZnS—SiO₂.

In addition, the second cover layer may comprise silicon oxide (SiO₂) and/or a metal oxide. In addition, the second cover layer may be composed of a mixture of silicon oxide (SiO₂) and metal oxide.

The mixture of silicon oxide (SiO₂) and metal oxide may be prepared from silicon oxide (SiO₂) and metal. Alternatively, the mixture may be prepared from silicon oxide (SiO₂) and metal oxide.

Examples of the metal that may be included in the second cover layer include Group IVB, VB, VIB, VIIB, and VIII metals, and Group IB, IIB, IIIA and IVA metals. In particular, Group IVB, VB, VIB, VIIB and VIII metals or Group IB, IIB, IIIA and IVA metals may be metals having oxide-forming capability. Examples of these metals include titanium (Ti), vanadium (V), chromium (Cr), manganese (Mn), iron (Fe), cobalt (Co), nickel (Ni), copper (Cu), zinc (Zn), zirconium (Zr), niobium (Nb), molybdenum (Mo), technetium (Tc), ruthenium (Ru), rhodium (Rh), palladium (Pd), silver (Ag), hafnium (Hf), tantalum (Ta), tungsten (W), rhenium (Re), osmium (Os), iridium (Ir), platinum (Pt), aluminum (Al), germanium (Ge), indium (In) and tin (Sn).

In addition, the metal for the second cover layer may be used alone or in combination thereof. As mentioned above, the metal may take the form of a metal oxide. Exemplary metal oxides include SiO₂/Sn oxides, SiO₂/Ti oxides, SiO₂/Zr oxides, SiO₂/Y oxides, SiO₂/Ta oxides, and SiO₂/In—Sn oxides.

The metal or metal oxide used for the second cover layer of the recording medium serves to increase a refractive index of the recording medium. The use of the metal oxide only may decrease the hardness of the recording medium. To prevent this decrease, the metal oxide may be used in conjunction with other materials. For example, silicon oxide (SiO₂) may be used. The cover layer of the recording medium for efficient recording and reproducing operations may be manufactured by suitably mixing silicon oxide and metal oxide. That is, the material for the second cover layer may be represented by Formula 1 below:

(SiO₂)₁₋ₓ+(Metal Oxide)ₓ (1)

wherein x is a mole fraction of the second cover layer, which is in the range of 0.1 to 0.9. In Formula 1, x is in the range of 0.2 to 0.8 and may be varied depending on the hardness or refractive index of the recording medium.

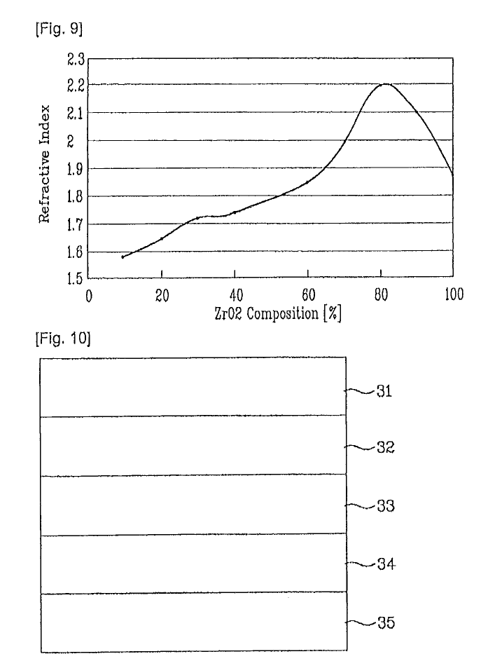

FIG. 9 is a curve showing refractive index as a function of mole fraction of the compound composition for the second cover layer. In FIG. 9, horizontal and vertical axes represent mole fraction and refractive index, respectively. For example, in FIG. 9, a refractive index according to a mole fraction of a ZrO₂/SiO₂ mixture is shown. As shown in FIG. 9, as the content of ZrO₂ as metal oxide, increases, a refractive index increases. In the area where the content of ZrO₂ is in the range of 80 to 100%, a refractive index decreases. This behavior is affected by the density of the ZrO₂/SiO₂ mixture. That is, when the content of ZrO₂ is 80% or higher, the density of the ZrO₂/SiO₂ mixture decreases, thus leading to a decrease in refractive index. Accordingly, the ZrO₂/SiO₂ mixture may contain SiO₂ in an amount of 20% or higher. In Formula 1, x may be 0.8 or less. In addition, as shown in FIG. 7, the ZrO₂/SiO₂ mixture may have a refractive index of 1.5 to 2.3.

The refractive index of the mixture of metal oxide and silicon oxide (SiO₂) may be varied depending on the kind of metal oxide. For example, a mixture composed of Ta₂O₅ and SiO₂ may have a refractive index of 1.5 to 2.1. As another example, a CeO₂—SiO₂ mixture may have a refractive index of 1.4 to 2.0.

In addition, methods for forming the second cover layer include physical vapor deposition (PVD), chemical vapor deposition (CVD) and the like. As one example of the PVD used in the present invention, an oxygen reactive co-sputtering method using silicon oxide and the metal may be used. As another example of the PVD, a co-sputtering method using silicon oxide and the metal oxide may be used.

In addition, as shown in FIG. 8, the recording medium may further comprise an information layer 30. The information layer 30 may comprise only a recording layer. Alternatively, the information layer 30 may comprise a recording layer and a layer to absorb heat generated from the recording layer. One embodiment of the information layer is shown in FIG. 10.

FIG. 10 illustrates an information layer according to one embodiment of the present invention. The information layer 30 may comprise a first protective layer 31, a recording layer 32, a second protective layer 33 and an anti-heat layer 34. Materials useful for the first protective layer 31 and the second protective layer 33 may be dielectrics. A material useful for the recording layer 32 may be a phase-transition material such as GeSbTe. The anti-heat layer may serve to release heat generated from the recording layer and be composed of silver (Ag) or a silver (Ag) alloy.

It will be apparent to those skilled in the art that various modifications and variations can be made in the present invention without departing from the spirit or scope of the invention.

Thus, it is intended that the present invention cover the modifications and variations of this invention provided they come within the scope of the appended claims and their equivalents.

### MODE FOR INVENTION

As apparent from the fore-going, the present invention was illustrated in the section “Best Mode”.

### INDUSTRIAL APPLICABILITY

The present invention provides a recording medium that ensures sufficient refractive index and strength and thus realizes efficient recording/reproducing operations, and a method for manufacturing the same. In addition, the recording medium and the method for manufacturing the same enable efficient recording/reproducing operations due to efficient energy transfer. Furthermore, the recording medium and the method for manufacturing the same are easy to control the thickness of a cover layer and can secure optical and mechanical properties suitable for recording/reproducing apparatuses by suitably controlling a mix ratio of a material of the cover layer.

1. A recording medium comprising:
a substrate;
a recording layer formed on the substrate;
a first cover layer having a first hardness formed on the recording layer; and
a second cover layer having a second hardness arranged on the first cover layer.

2. The recording medium according to claim 1, wherein the second hardness is higher than the first hardness.

3. The recording medium according to claim 2, wherein the first hardness is 2H or less.

4. The recording medium according to claim 2 wherein the second hardness is 2H or higher.

5. The recording medium according to claim 1 wherein the first cover layer has a first refractive index, and the second cover layer has a second refractive index.

6. The recording medium according to claim 5, wherein the second refractive index is higher than the first refractive index.

7. The recording medium according to claim 1, wherein the recording medium is recorded/reproduced by a recording/reproducing apparatus comprising an optical system.

8. The recording medium according to claim 7, wherein the second refractive index of the second cover layer of the recording medium is higher than a numerical aperture of the optical system.

9. The recording medium according to claim 1, wherein the first cover layer is composed of at least one of a polymer and a nanocomposite.

10. The recording medium according to claim 1, wherein the second cover layer is composed of at least one dielectric material.

11. The recording medium according to claim 10, wherein the second cover layer comprises at least one of Si₃N₄ and ZnS.

12. The recording medium according to claim 1, wherein the second cover layer comprises silicon oxide (SiO₂).

13. The recording medium according to claim 12, wherein the second cover layer further comprises metal oxide.

14. The recording medium according to claim 13, wherein the second cover layer is composed of a compound, (SiO₂)₁₋ₓ+(metal oxide)ₓ.

15. The recording medium according to claim 14, wherein x of the compound is 0.1 to 0.9.

16. The recording medium according to claim 14, wherein x of the compound is 0.2 to 0.8.

17. The recording medium according to claim 13, wherein the metal oxide is at least one selected from Ti, V, Cr, Mn, Fe, Co, Ni, Cu, Zn, Zr, Nb, Mo, Tc, Ru, Rh, Pd, Ag, Hf, Ta, W, Re, W, Os, Ir, Pt, Al, Ge, In and Sn oxides.

18. The recording medium according to claim 1, wherein the second cover layer has a refractive index of 1.5 to 2.2.

19. The recording medium according to claim 1, wherein a total thickness of the first cover layer and the second cover layer is 1 to 5 μm.

20. The recording medium according to claim 1, wherein the second cover layer is an anti-reflective layer.

21. A method for manufacturing a recording medium comprising:
forming a recording layer on a substrate;
forming a first cover layer having a first hardness on the recording layer; and
forming a second cover layer having a second hardness on the first cover layer.

22. The method according to claim 21, wherein the second cover layer is formed by physical vapor deposition (PVD) or chemical vapor deposition (CVD).

23. The method according to claim 21, wherein the second hardness is higher than the first hardness.

24. The method according to claim 21, wherein the first hardness is 2H or less.

25. The method according to claim 21, wherein the second hardness is 2H or higher.

26. The method according to claim 21, wherein the first cover layer has a first refractive index, and the second cover layer has a second refractive index.

27. The method according to claim 26, wherein the second refractive index is higher than the first refractive index.

28. The method according to claim 21, wherein the recording medium is recorded/reproduced by a recording/reproducing apparatus comprising an optical system.

29. The method according to claim 28, wherein the second refractive index of the second cover layer of the recording medium is higher than a numerical aperture of the optical system.

30. The method according to claim 21, wherein the first cover layer is composed of at least one of a polymer and a nanocomposite.

31. The method according to claim 21, wherein the second cover layer is composed of at least one dielectric material.

32. The method according to claim 31, wherein the second cover layer comprises at least one of Si₃N₄ and ZnS.

33. The method according to claim 21, wherein the second cover layer comprises silicon oxide (SiO₂).

34. The method according to claim 21, wherein the second cover layer further comprises metal oxide.

35. The method according to claim 34, wherein the second cover layer is composed of a compound, (SiO₂)₁₋ₓ+(metal oxide)ₓ.

36. The method according to claim 35, wherein x of the compound is 0.1 to 0.9.

37. The method according to claim 35, wherein x of the compound is 0.2 to 0.8.

38. The method according to claim 34, wherein the metal oxide is at least one selected from Ti, V, Cr, Mn, Fe, Co, Ni, Cu, Zn, Zr, Nb, Mo, Tc, Ru, Rh, Pd, Ag, Hf, Ta, W, Re, W, Os, Ir, Pt, Al, Ge, In and Sn oxides.

39. The method according to claim 21, wherein the second cover layer has a refractive index of 1.5 to 2.2.

40. The method according to claim 21, wherein a total thickness of the first cover layer and the second cover layer is 1 to 5 μm.

41. The method according to claim 21, wherein the second cover layer is an anti-reflective layer.
